(19) United States
(12) Patent Application Publication
(10) Pub. No.: US 2011/0147870 A1
(43) Pub. Date: Jun. 23, 2011

(54) PHOTODETECTOR WITH VALENCE-MENDING ADSORBATE REGION AND A METHOD OF FABRICATION THEREOF

(76) Inventors: Kah Wee Ang, Singapore (SG); Guo-Qiang Patrick Lo, Singapore (SG); Mingbin Yu, Singapore (SG)

(21) Appl. No.: 12/867,659

(22) PCT Filed: May 30, 2008
(86) PCT No.: PCT/SG2008/000199

§ 371 Date: Mar. 2, 2011

Related U.S. Application Data
(60) Provisional application No. 61/029,039, filed on Feb. 15, 2008.

(51) Int. Cl. H01L 31/0232; H01L 31/18; H01L 31/0224

(52) U.S. Cl. 257/432; 438/98; 257/431; 257/E31.127; 257/E31.124

(57) ABSTRACT

According to an embodiment, a photodetector is provided, including a detector region, a first contact region forming an interface with the detector region, and a first valence mending adsorbate region between the first contact region and the detector region.

### TECHNICAL FIELD

Embodiments relate to a photodetector and a method of fabrication thereof.

### BACKGROUND

Germanium-on-SOI (semiconductor on insulator), or commonly abbreviated as Ge-on-SOI, is commonly used in near-infrared photo-detection applications due to Ge-on-SOI integration compatibility with existing CMOS technology, and large absorption coefficient. p-i-n Ge photodetectors exhibit good responsivity and quantum efficiency for optical absorption at a wavelength λ of 850 nm with potential for longer wavelength L-band photo-detection (λ=1561-1620 nm). In a conventional photodetector, a metal-semiconductor-metal (MSM) structure is utilised to leverage on the advantage of low junction capacitance and ease of process integration.

However, high dark current observed in a MSM photodetector causes the photodetector to have a poor signal-to-noise ratio, which is further aggravated when a narrow bandgap material such as Ge is employed for the active photodetector region, where high dark current is predominantly attributed to low Schottky barrier height. The low hole Schottky barrier is due to strong Fermi level pinning at the electrode(metal)/photodetector(Ge) interface at a charge neutrality level, which shows little dependence on the choice of metal work function employed. For instance, a germanium MSM photodetector integrated in a SOI rib waveguide may have a high dark current performance in the order of 150 μA for a given applied bias of 1 V.

One conventional device suppresses dark current by introducing a large band gap energy material, such as a thin film of amorphous-Si or amorphous-Ge, that is continuous at the interface between an electrode and the semiconductor. Using amorphous-Si or amorphous-Ge as barrier materials increase parasitic resistance, leading to a compromise in the photocurrent.

It would be desired to have a photodetector that reduces the dark current phenomena without at least some of the deficiencies mentioned above.

### SUMMARY

In an embodiment, a photodetector is provided, including a detector region, a first contact region forming an interface with the detector region, and a first valence mending adsorbate region between the first contact region and the detector region.

In another embodiment, there is provided a method of forming a photodetector. The method may include forming a detector region, forming a first contact region as an interface with the detector region, and a first valence mending adsorbate region between the first contact region and the detector region.

In yet another embodiment, there is provided a photodetector including a detector region, a first contact region, and a first valence mending adsorbate region forming an interface between the detector region and the first contact region, wherein the first valence mending adsorbate region passivates dangling bonds between the first contact region and the detector region.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of various embodiments. In the following description, various embodiments are described with reference to the following drawings, in which:

FIG. 1 shows a scanning electron microscopy (SEM) image of a photodetector built in accordance with an embodiment.

FIG. 2 shows a cross-sectional view of a photodetector built in accordance with an embodiment.

FIG. 3A shows a cross-sectional view of a photodetector without a valence mending adsorbate region.

FIG. 3B shows a band gap diagram for a photodetector without a valence mending adsorbate region.

FIG. 3C shows a cross-sectional view of a photodetector built in accordance with an embodiment.

FIG. 3D shows a band gap diagram for a photodetector built in accordance with an embodiment.

FIG. 4 shows a photodetector built in accordance with an embodiment.

FIG. 5 shows a flow chart of a fabrication process to manufacture a photodetector built in accordance with an embodiment.

FIGS. 6A to 6F show cross-sectional views of several fabrication stages of a photodetector according to an embodiment.

FIGS. 7A and 7B show high resolution transmission electron microscopy (HRTEM) images of a NiGe/Ge junction in a photodetector built in accordance with an embodiment.

FIG. 7C shows a secondary-ion-mass spectroscopy (SIMS) depth profile of a sulfur-segregated NiGe Schottky contact of a photodetector built in accordance with an embodiment.

FIG. 8 is a plot of room-temperature current-voltage (I-V) curves.

FIGS. 9A and 9B are plots of current versus applied voltage V_{A}.

FIG. 10 is a plot of response (dB) versus frequency (Hz) for a photodetector built in accordance with an embodiment.

### DETAILED DESCRIPTION

While embodiments have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced. It will be appreciated that common numerals, used in the relevant drawings, refer to components that serve a similar or the same purpose.

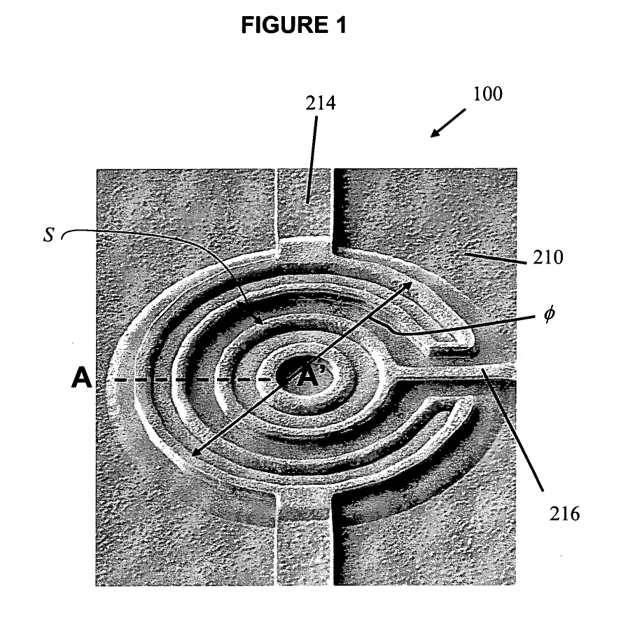

FIG. 1 shows a scanning electron microscopy (SEM) image of a photodetector 100 built in accordance with an embodiment.

From FIG. 1, it can be observed that the photodetector 100 includes a first electrode 216 and a second electrode 214, both disposed above a passivation layer 210. In the embodiment shown, the photodetector 100 has an effective diameter φ of around 32 μm and a finger spacing S of around 2.0 μm.

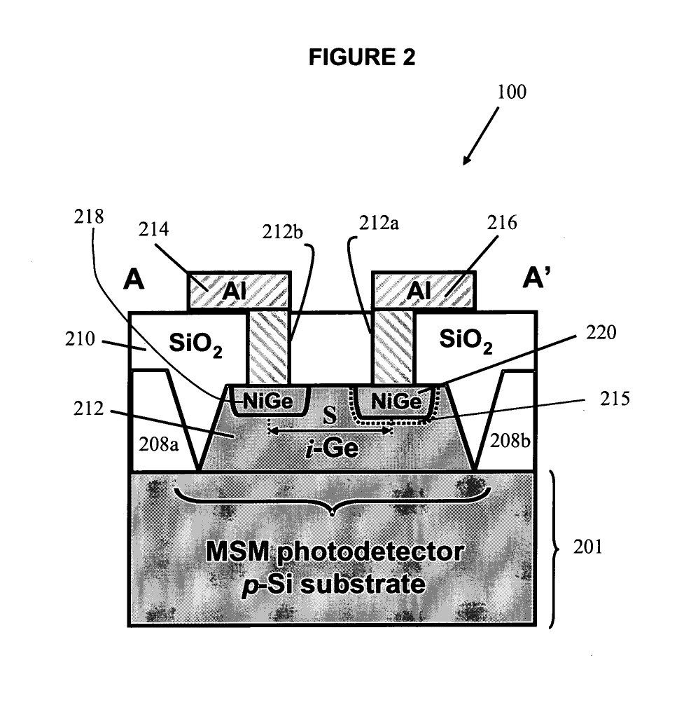

FIG. 2 shows a cross-sectional view, taken along line A-A′ of FIG. 1, of the photodetector 100 built in accordance with an embodiment.

The photodetector 100 includes a bulk substrate layer 201; a detector region 212; isolation regions 208a and 208b; the passivation layer 210; a first contact region 220; a second contact region 218; a first valence mending adsorbate region 215; the first electrode 216; and the second electrode 214.

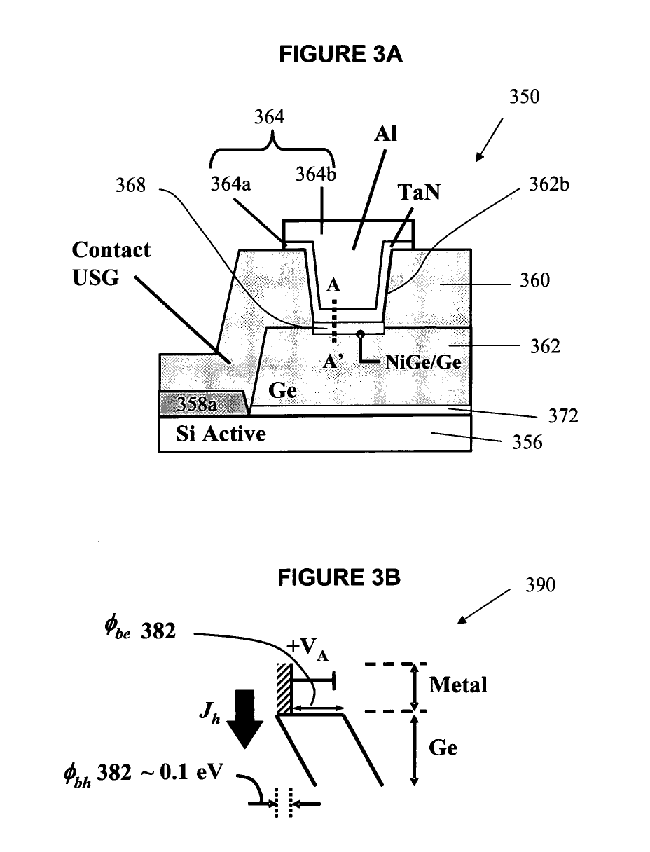

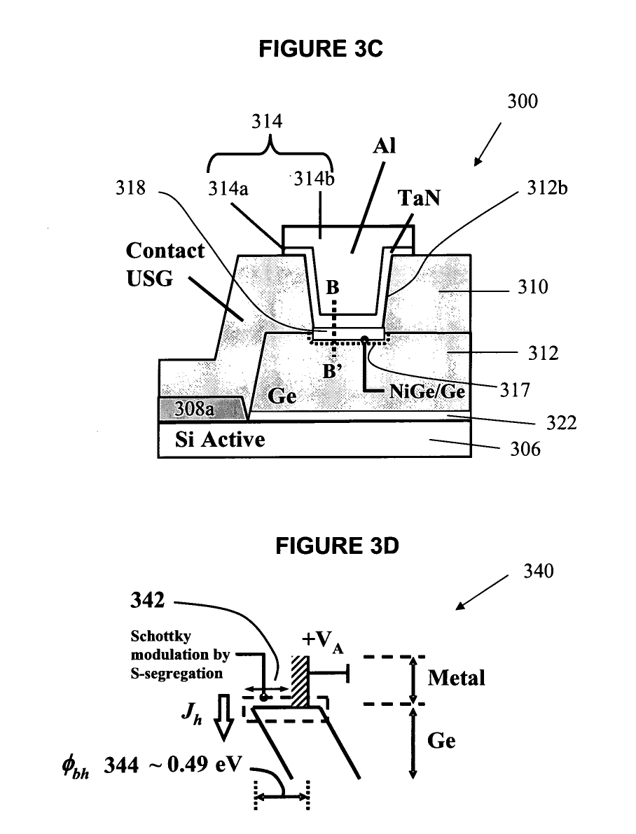

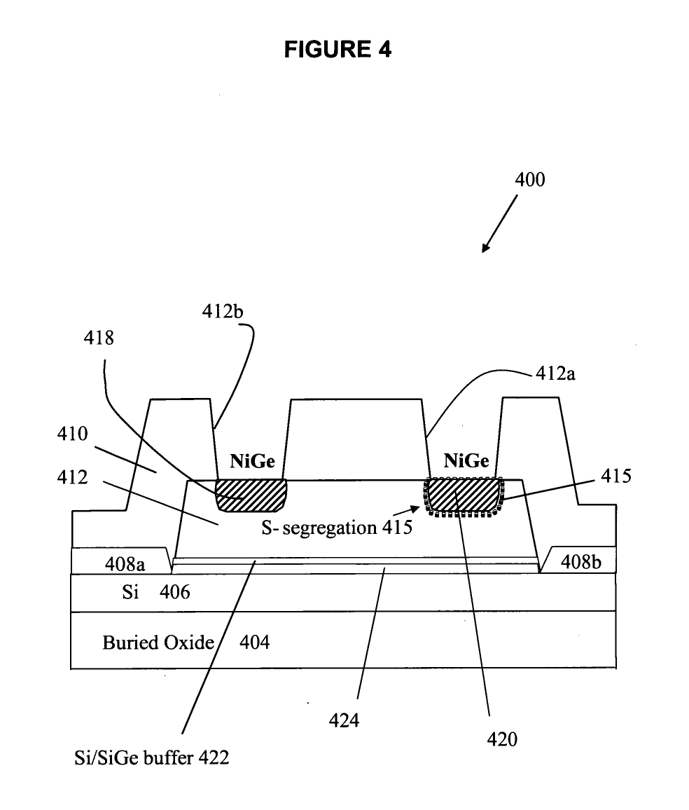

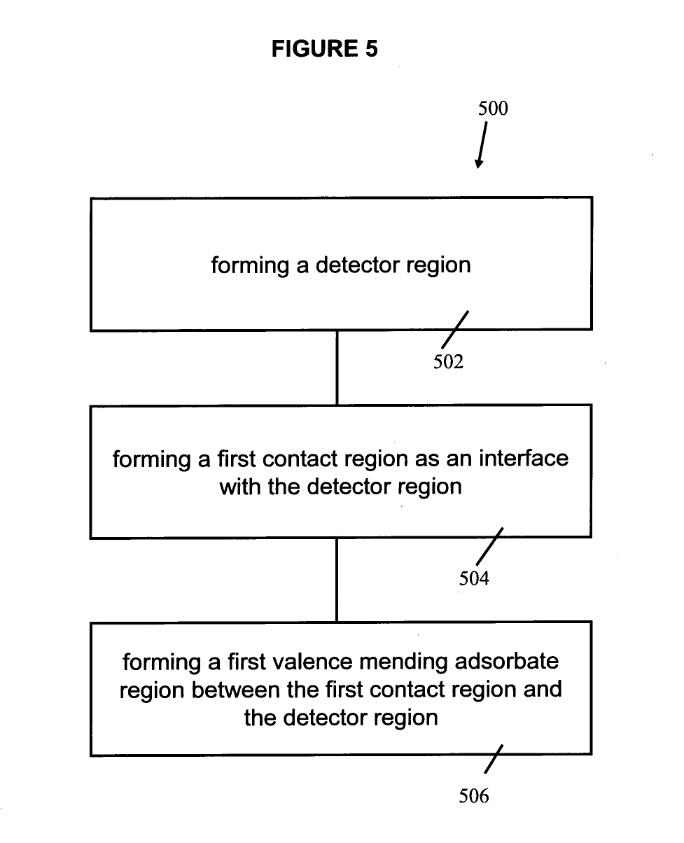

The first contact region 220 forms an interface with the detector region 212, wherein the first valence mending adsorbate region 215 is disposed between the first contact region 220 and the detector region 212. Similarly, the second contact region 218 forms an interface with the detector region 212. In another embodiment (see FIG. 3C), a second valence mending adsorbate region (compare reference numeral 317) is disposed between the second contact region and the detector region.

In the embodiment shown in FIG. 2, the first contact region 220 forms the interface with the detector region 212 by being in contact with the detector region 212 so that the upper surface of the first contact region 220 is flush with the upper surface of the detector region 212. This allows the first electrode 216 to directly contact the upper surface of the first contact region 220. In another embodiment (not shown), both the first contact region and the first valence mending adsorbate region are formed within or embedded inside the detector region.

It will be appreciated that in another embodiment (not shown), the first contact region may be disposed above the detector region. The first valence mending adsorbate region may be disposed between the detector region and the first contact region so that the upper surface of the first valence mending region is flush with the upper surface of the detector region.

Returning to the embodiment shown in FIG. 2, the second contact region 218 forms an interface with the detector region 212 by being in contact with the detector region 212 so that the upper surface of the second contact region 218 is flush with the upper surface of the detector region 212. This allows the second electrode 214 to directly contact the upper surface of the second contact region 218. In addition, the second contact region 218 is electrically isolated from the first contact region 220 by the portion of the detector region 212 therebetween. In another embodiment (not shown), both the second contact region and the second valence mending adsorbate region are formed within or embedded inside the detector region.

Turning to FIG. 3C, which shows another embodiment of a photodetector 300 built in accordance with an embodiment, a second contact region 318 may be disposed above the detector region 312. A second valence mending adsorbate region 317 may be disposed between the detector region 312 and the second contact region 318 so that the upper surface of the second valence mending adsorbate region 317 is flush or substantially flush with the upper surface of the detector region 312.

The second valence mending adsorbate region 317 effectively passivates dangling bonds at the interface between the second contact region 318 and the detector region 312. Similarly, with reference to FIG. 2, the first valence mending adsorbate region 215 effectively passivates dangling bonds at the interface between the first contact region 220 and the detector region 212.

In one embodiment (not shown), the passivation layer may be disposed above the detector region. The passivation layer only has a first trench, wherein both a first contact region and a first valence mending adsorbate region are disposed in the first trench.

In another embodiment (not shown), the passivation layer may be disposed above the detector region. The passivation layer has a first trench and a second trench, so that the region of the passivation layer between the first trench and the second trench is discontinuous from the remainder of the passivation layer. Both the first contact region and the first valence mending adsorbate region are disposed in the first trench. On the other hand, both the second contact region and the second valence mending adsorbate region are disposed in the second trench.

Returning to the embodiment shown in FIG. 2, the detector region 212 may be disposed above the bulk substrate layer 201, while the isolation regions 208a and 208b are disposed above the bulk substrate layer 201 and adjacent to opposing edges of the detector region 212.

The passivation layer 210 is disposed above the detector region 212. The passivation layer 210 has a first trench 212a and a second trench 212b. The region of the passivation layer 210 between the first trench 212a and the second trench 212b is discontinuous from the remainder of the passivation layer 210. Both the first contact region 220 and the first valence mending adsorbate region 215 are disposed in the first trench 212a. The second contact region 218 is disposed in the second trench 212b.

The first trench 212a and the second trench 212b define openings within the passivation layer 210 to portions of the detector region 212 at the base of the first trench 212a and the second trench 212b. Within these openings, the first contact region 220 forms an interface with the detector region 212, while the second contact region 218 forms an interface with the detector region 212. As mentioned above, the second contact region 218 is electrically isolated from the first contact region 220 by the region of the detector region 212 therebetween (i.e. in between the first contact region 220 and the second contact region 218).

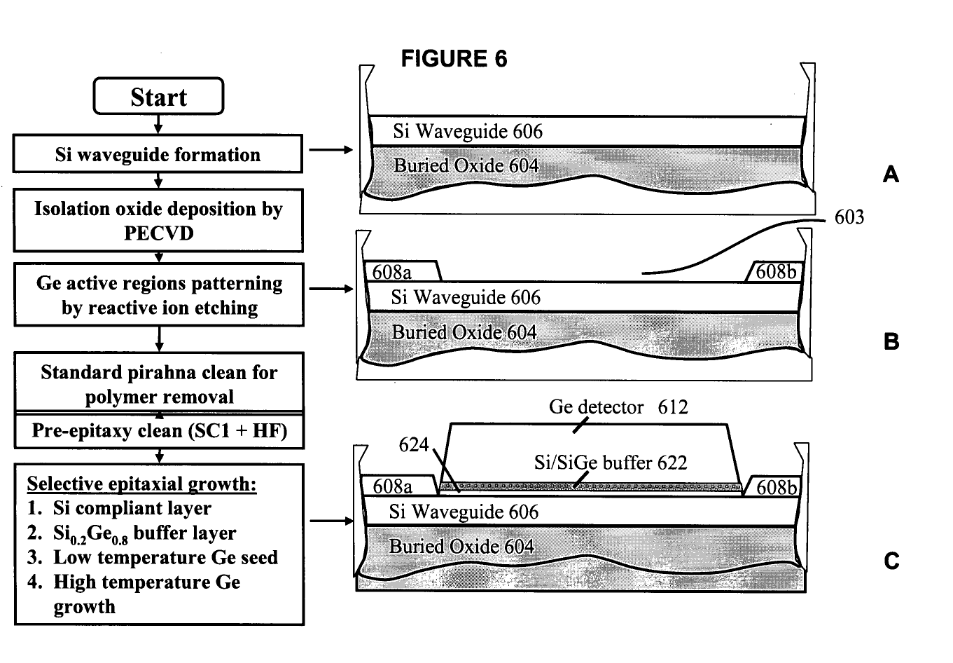

It will be appreciated that the bulk substrate layer 201 further includes an isolation layer/buried oxide layer (see reference numeral 404 in FIG. 4) and a waveguide layer (see reference numeral 406 in FIG. 4). The waveguide layer is below the detector region 212, i.e. the detector region 212 is disposed above the waveguide layer, so that the isolation regions 208a and 208b are disposed above the waveguide layer and adjacent to opposing edges of the detector region 212. The waveguide layer is disposed above the isolation layer/buried oxide layer (see FIG. 4).

In another embodiment (see FIG. 4), the photodetector 100 may further include a buffer layer (compare reference numeral 422 in FIG. 4) and a compliant layer (compare reference numeral 424 in FIG. 4). The compliant layer is disposed above the waveguide layer, while the buffer layer is disposed above the compliant layer. The detector region 212 is disposed above the buffer layer. Thus, the buffer layer is disposed between the detector region and the waveguide layer, while the compliant layer is disposed between the buffer layer and the waveguide layer 206.

In the embodiment shown in FIG. 2 the first electrode 216 is disposed above the first contact region 220 and is in contact with the first trench 212a. Similarly, the second electrode 216 is disposed above the second contact region 218 and in contact with the second trench 212b.

The first valence mending adsorbate region 215 is a segregated region at the interface between the first contact region 220 and the detector region 212. Similarly, in the embodiment (see FIG. 3C) where the second valence mending adsorbate region is present, the second valence mending adsorbate region is a segregated region at the interface between the second contact region 218 and the detector region 212.

The valence mending adsorbate regions enable Schottky barrier height modulation. In FIG. 2, where nickel germanide (NiGe) is used for the first contact region 220 and germanium (Ge) is used for the detector region 212, co-implantation and segregation of sulfur as the valence mending absorbate region 215 at the NiGe/Ge interface allows the Fermi level of germanide to be pinned close to the conduction band edge. This results in a modulation of hole Schottky barrier height, leading to a dark current suppression of more than 3 orders of magnitude over a conventional metal-semiconductor-metal (MSM) photodetector (i.e. a photodetector without the valence mending absorbate region 215). When operated at a bias voltage V_{A} of 1.0 V, a photodetector 100 with an area of 804 μm² shows a spectra response of around 0.36 A/W or a corresponding quantum efficiency of around 34%. In addition, a frequency response measurement reveals the achievement of an around −3 dB bandwidth of around 15 GHz at an illumination photon wavelength of 1550 nm.

The approach of using a valence mending adsorbate as a segregation region at the interface between the first or second contact regions (220, 218) and the detector region 212 allows local engineering of the hole Schottky barrier through selective implantation without affecting the optical properties of the detector region 212. Compared with conventional photodetectors, the contact resistance experienced by the electrodes 216 and 214 is lower which results in improved carrier collection frequency and a lower dark current for a reverse biasing voltage.

FIGS. 3A to 3D illustrate how a band gap diagram 340 for the photodetector 300 built in accordance with an embodiment of the invention is affected when compared to a band gap diagram 390 for a photodetector 350 without a valence mending adsorbate region.

FIG. 3A shows a cross-sectional view of the photodetector 350 without a valence mending adsorbate region.

The photodetector 350 includes a waveguide layer 356; a detector region 362; an isolation region 358a; a passivation layer 360; a second contact region 368; a buffer layer 372; and a second electrode 364.

The second contact region 368 forms an interface with the detector region 362. The buffer layer 372 is disposed above the waveguide layer 356, while the detector region 362 is disposed above the buffer layer 372. The isolation region 358a is disposed above the waveguide layer 356 and adjacent to an opposing edge of the detector region 362. The passivation layer 360 is disposed above the isolation region 358a and the detector region 362.

The second electrode 364 includes at least a first conductive material 364a and a second conductive material 364b, wherein it is the first conductive material 364a that is in contact with both the second contact region 368 and a second trench 362b formed in the passivation layer 360.

The photodetector 350 can be represented by two back-to-back Schottky diodes. In the absence of image force lowering effects, the Ge photo-detection region 362 between the second electrode 364 and the waveguide layer 356 will be totally depleted under high applied bias. The total dark current J_{Total} flowing through the photodetector 602 can then be described by the following expression:

J_{Total}=Jₚ+Jₙ=Aₚ*T²e^{-qφ}^{_{bh}}^{/kT}+Aₙ*T²e^{-qφ}^{_{be}}^{/kT} (1)

where Jₚ(Jₙ) is the hole (electron) current injected from the anode (cathode), and Aₚ* (Aₙ*) is the Richardson's constant for hole (electron). Both the hole current and electron current are observed to contribute to the dark current in the photodetector 350, which exhibit a strong dependence on the Schottky barrier for hole (φ_{bh}) and electron (φ_{be}), respectively. According to the Schottky-Mott theory on ideal metal-semiconductor system, the Schotkky barrier height (φ_{B}) can be determined from the difference of the metal work function (φₘ) and the electron affinity of the semiconductor (χ_{S}), i.e. φ_{B}=φₘ−χ_{S}. However, in practice, the presence of interface states has been shown to result in the Schottky barrier height being less dependent on the metal work function. Strong Fermi level pinning feature of the second electrode 364 and the detector 362 junction contributes to a high electron Schottky barrier φ_{be} 380, and thus leading to low hole Schottky barrier φ_{bh} 382 of around 0.1 eV. As a consequence, the hole current dominates over the electron current in affecting the dark current of the MSM (metal semiconductor metal) photodetector 350, as schematically illustrated by the band diagram 390 in FIG. 3B, which is taken along line A-A′ of FIG. 3A.

FIG. 3C shows a cross-sectional view of the photodetector 300 built in accordance with an embodiment.

The photodetector 300 includes a waveguide layer 306; a detector region 312; an isolation region 308a; a passivation layer 310; a second contact region 318; a buffer layer 322; a second valence mending adsorbate region 317; and a second electrode 314.

The second contact region 318 forms an interface with the detector region 312, wherein the second valence mending adsorbate region 317 is disposed between the second contact region 318 and the detector region 312. In the embodiment shown in FIG. 3C, the second contact region 318 forms the interface with the detector region 312 by being in contact with the detector region 312 so that the upper surface of the second contact region 318 is flush or substantially flush with the upper surface of the detector region 312.

The buffer layer 322 is disposed above the waveguide layer 306, while the detector region 312 is disposed above the buffer layer 322. The isolation region 308a is disposed above the waveguide layer 306 and adjacent to an opposing edge of the detector region 312. The passivation layer 310 is disposed above the isolation region 308a and the detector region 312.

The second electrode 314 includes at least a first conductive material 314a and a second conductive material 314b, wherein it is the first conductive material 314a that is in contact with both the second contact region 318 and a second trench 312b formed in the passivation layer 310.

FIG. 3D shows the band gap diagram 340, which is taken along line B-B′ of FIG. 3C. As mentioned above, the valence mending adsorbate region brings about a modulation of hole Schottky barrier height. Comparing FIG. 3D with FIG. 3C, an increase in the hole Schottky barrier height 342 is attained. For the embodiment shown in FIG. 3D, the hole Schottky barrier φ_{bh} 344 is around 0.49 eV.

FIG. 4 shows a photodetector 400 built in accordance with an embodiment.

The photodetector 400 includes an isolation layer/buried oxide layer 404; a waveguide layer 406; a compliant layer 424; a buffer layer 422, a detector region 412; isolation regions 408a and 408b; a passivation layer 410; a first contact region 420; a second contact region 418; and a first valence mending adsorbate region 415.

The waveguide layer 406 is disposed above the buried oxide 404. The detector region 412 is disposed above the waveguide layer 406. The isolation regions 408a and 408b are disposed above the waveguide layer 406 and adjacent to opposing edges of the detector region 412.

The passivation layer 410 is disposed above the detector region 412, wherein the passivation layer 410 has a first trench 412a and a second trench 412b. The first trench 412a and the second trench 412b define openings within the passivation layer 410 to portions of the detector region 412 at the base of the first trench 412a and the second trench 412b. The region of the passivation layer 410 between the first trench 412a and the second trench 412b is discontinuous from the remainder of the passivation layer 410.

Within the first trench 412a, the first contact region 420 forms an interface with the detector region 412, wherein the first valence mending adsorbate region 415 is disposed between the first contact region 420 and the detector region 412. Similarly, within the second trench 412b, the second contact region 418 forms an interface with the detector region 412. A second valence mending adsorbate region (not shown) may be disposed between the second contact region 418 and the detector region 412.

In the embodiment shown in FIG. 4, the first contact region 420 forms the interface with the detector region 412 by being in contact with the detector region 412 so that the upper surface of the first contact region 420 is flush with the upper surface of the detector region 412. This allows a first electrode (not shown, but compare first electrode 216 of FIG. 2) to directly contact the upper surface of the first contact region 420.

Similarly, the second contact region 418 forms an interface with the detector region 412 by being in contact with the detector region 212 so that the upper surface of the second contact region 418 is flush with the upper surface of the detector region 412. This allows a second electrode (not shown, but compare second electrode 214 of FIG. 2) to directly contact the upper surface of the first contact region 420.

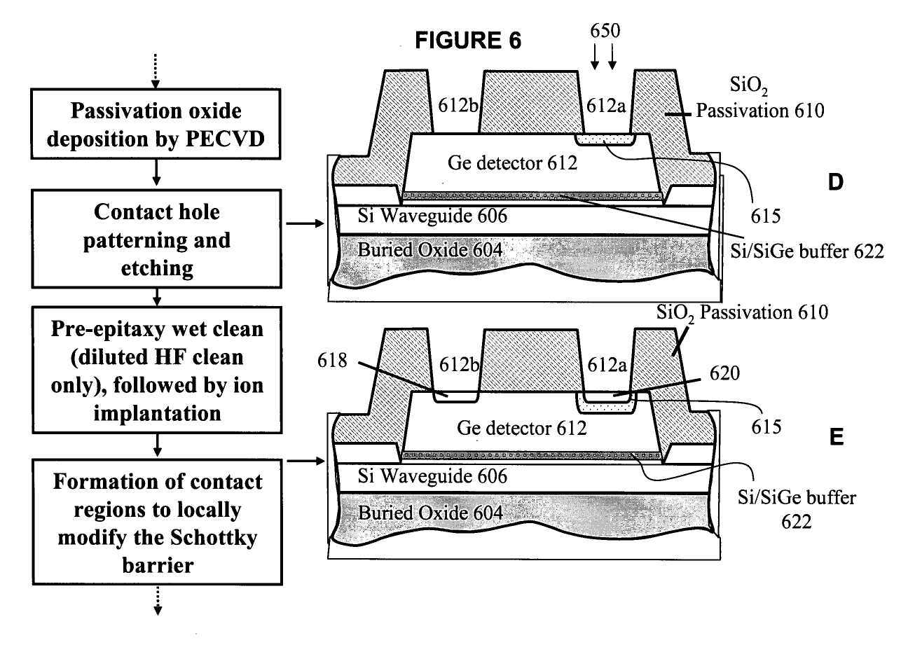

FIG. 5 shows a flow chart 500 of a fabrication process to manufacture a photodetector built in accordance with an embodiment.

The fabrication process begins at step 502 with the forming of a detector region. In step 504, a first contact region is formed as an interface with the detector region. In step 506, a first valence mending adsorbate region is formed between the first contact region and the detector region.

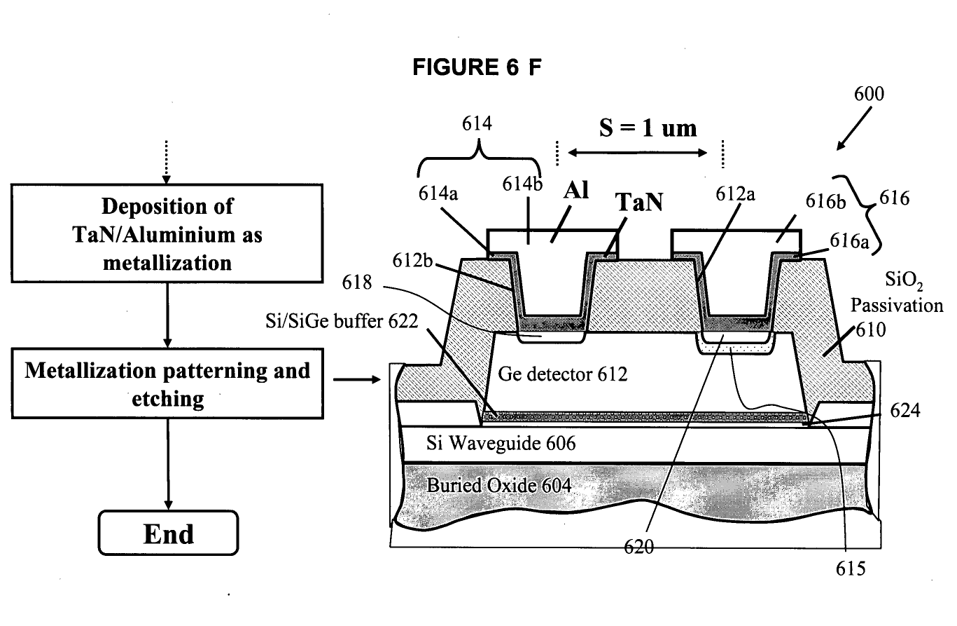

Further detail on the fabrication process outlined in flow chart 500 is described with reference to FIGS. 6A to 6F.

FIGS. 6A to 6F show cross-sectional views of several fabrication stages of a photodetector 600 according to an embodiment of the present invention.

In one embodiment, the photodetector 600 may be a Ge MSM (germanium 612 metal semiconductor metal) photodetector fabricated on an 8 inch SOI (silicon-on-insulator) substrate with (100) surface orientation.

Starting with FIG. 6A, an isolation layer/buried oxide layer 604 is formed above a substrate layer (not shown). A silicon waveguide layer 606 is formed by dry etching or deposition on the isolation layer/buried oxide layer 604. The silicon waveguide layer 606 and the isolation layer/buried oxide layer 604 form a SOI substrate having a silicon body thickness of around 250 nm and a buried oxide thickness of around 1 μm.

Plasma enhanced chemical vapor deposition (PECVD) oxide of around 120 nm thickness is then deposited on the silicon waveguide layer 606. As shown in FIG. 6B, the PECVD oxide is patterned by reactive ion etching, thereby forming the isolation regions 608a and 608b defining an active window 603 between the isolation regions 608a and 608b. The active window 603 allows for the formation of a Ge detector region 612 (see FIG. 6C) on the silicon waveguide layer 606, where the isolation regions 608a and 608b are adjacent to opposing edges of the detector region 612 (FIG. 6C) that will be subsequently formed.

The wafer is then subjected to pre-epitaxy cleaning using a standard SC1 (NH₄OH:H₂O₂: H₂O) clean and a HF-last wet process.

Ge epitaxy growth, in an ultra high vacuum chemical vapor deposition (UHVCVD) reactor, first starts with an in-situ baking in nitrogen (N₂) ambient at 800° C. for native oxide removal.

A Si compliant layer 624 of around 5 nm thickness is deposited at around 530° C. through the active window 603. A silicon-germanium (SiGe) buffer layer 622 of around 10 nm thickness with [Ge] of around 20% is then deposited on the Si compliant layer 624 to minimize lattice mismatch with an eventually deposited Ge detector region 612 (see FIG. 6C) and have a gradual transition at the interface between the Si waveguide layer 606 and the eventually deposited Ge detector region 612 (see FIG. 6C). A low temperature growth at around 370° C. is subsequently employed to form a Ge seed of around 30 nm thickness, before the high temperature Ge deposition of around 300 nm thickness and at around 550° C. to form the Ge detector region 612, as shown in FIG. 6C. Precursor gases including pure disilane Si₂H₆ and diluted germane GeH₄ (10% GeH₄:90% Ar) were employed for the epitaxy growth of the SiGe buffer layer 622 and the Ge detector region 612. The RMS surface roughness and the defects density of the Ge epilayer were measured to be around 1.2±0.2 nm and around 6×10⁶ cm⁻², respectively. It will thus be appreciated that forming the Ge detector region 612 may further include forming the SiGe buffer layer 622 between the Ge detector region 612 and the silicon waveguide layer 606, and forming the Ge detector region 612 may further include forming the Si compliant layer 624 between the buffer layer 622 and the silicon waveguide layer 606.

In another embodiment (refer FIG. 2A) the Ge detector region 612 may be directly formed on a bulk substrate layer.

In FIG. 6D, PECVD oxide deposition is performed to form the passivation layer 610, of around 320 nm thickness, above the detector region 612 and the isolation regions 608a and 608b. The passivation layer 610 is then contact hole patterned to create a first trench 612a and a second trench 612b within the passivation layer 610. Ion implantation 650 of valence mending absorbate, such as sulfur (S) with a dose of 1×10¹⁵ cm⁻² and at an implant energy of 10 KeV is selectively performed in the first trench 612a so that a first valence mending absorbate region 615 is formed in the Ge detector region 612. It will be appreciated that the ion implantation can also be performed in the second trench 612b, so that a second valence mending absorbate region (not shown) is formed in the Ge detector region 612.

The ion implantation 650 step can be integrated into existing CMOS fabrication processes, thus facilitating use of the fabrication process outlined in the flow chart 500 (see FIG. 5) in full optoelectronics integrated circuit applications. Further, the ion implantation 650 step provides the advantage of easy modulation, in a localized manner, of the Schottky barrier height by adjusting the dose of the species being implanted compared to photodetectors which use two different set of electrodes with different work functions to modulate the Schottky barrier height.

After diluted HF clean, nickel (Ni) films with a thickness of 30 nm are deposited in both the trenches 612a and 612b. A germanidation process is then performed, as shown in FIG. 6E, at a RTA (Rapid Thermal Anneal) of 500° C. for 30 seconds in N₂ ambient to form the nickel-monogermanide (NiGe) first and second contact regions 620 and 618 respectively. The sulfur first valence mending absorbate region 615 will then be disposed between the first contact region 620 and the detector region 612.

While the germanidation front proceeds, the implanted sulfur atoms 650 are observed to segregate at the interface between the NiGe first contact region 620 and the Ge detector 612. Due to this segregation, the dangling bonds at the NiGe/Ge interface can be effectively passivated, resulting in the pinning of germanide Fermi level close to the conduction band edge. In this manner, local Schottky barrier modulation is achieved without affecting the optical characteristics of the eventually fabricated Ge photodetector 600 (see FIG. 6F).

A photodetector (not shown) without the first valence mending absorbate region 615 may also be fabricated to act as a control sample.

FIG. 6F shows the metallization stage. A first electrode 616 is deposited above the first contact region 620 and in contact with the first trench 612a; and a second electrode 614 is deposited above the second contact region 618 and in contact with the second trench 612b. The first electrode 616 includes at least a first conductive material 616a and a second conductive material 616b, wherein it is the first conductive material 616a that is in contact with both the first contact region 620 and the first trench 612a. Similarly, the second electrode 614 includes at least a first conductive material 614a and a second conductive material 614b, wherein it is the first conductive material 614a that is in contact with both the second contact region 618 and the second trench 612b. The first conductive materials 616a and 614a may each be tantalum nitride (TaN) of around 200 Å to around 500 Å, while the second conductive materials 616b and 614b may each be aluminum (Al) of around 6000 Å. The first electrode 616 and the second electrode 614 are patterned and etched to desired shapes. The spacing S between the metal contacts of the device is around 1 μm.

Example dimensions for a photodetector (100, 300, 400 and 600) built in accordance with an embodiment are as follows. The thickness of the isolation/buried oxide layer (404 and 604) is around 1 μm, while the thickness of the waveguide layer (306, 406 and 606) is around 200 nm. The thickness of the isolation regions (208a and 208b; 308a; 408a and 408b; and 608a and 608b) is around 120 nm each. The thickness of the passivation layer (210, 310, 410 and 610) is around 320 nm. The first electrode (216 and 616) and the second electrode (214 and 614) are separated by a distance of around S=around 0.1 μm to around 10 μm. Smaller finger spacing S is desirable for better speed performance.

Example materials used to realize a photodetector (100, 300, 400 and 600) built in accordance with an embodiment of the invention are as follows. Both the first contact region (220, 420 and 620) and the second contact region (218, 318, 418 and 618) may be made of material from any one or more of a group consisting of nickel-germanide, nickel-platinum-germanide, nickel-titanium-germanide, and platinum-germanide. Both the first valence mending adsorbate region (215, 415 and 615) and the second valence mending adsorbate region (317) may be made of material from any one or more of a group consisting of sulfur, selenium and tellurium. The detector regions (212, 312, 412 and 612) may be made of material from any one or more of a group consisting of germanium, silicon, silicon-germanium-silicon and silicon-germanium-germanium quantum well. The passivation layer (210, 310, 410 and 610) may be made of insulating materials from any one or more of group insulating materials consisting of silicon dioxide, silicon nitride, silicon oxynitride and undoped silicate glass. The waveguide layer (206, 306, 406 and 606) may be made of material from a group consisting of silicon, poly-silicon, silicon nitride and silicon oxynitride. Other material that has a higher refractive index than the isolation/buried oxide layer (404 and 604) and/or any transparent materials to the operating wavelength of the photodetector (100, 300, 400 and 600) can also be used for the waveguide layer (206, 306, 406 and 606). The buffer layer (322, 422 and 622) may be made of material from any one or more of a group consisting of silicon, silicon-germanium and silicon-germanium-carbon. The compliant layer (424 and 624) may be made of material from any one or more of a group consisting of silicon, silicon-germanium and silicon-germanium-carbon. The isolation regions (208a and 208b; 308a; 408a and 408b; and 608a and 608b) may be made of insulating materials from any one or more of a group consisting of silicon dioxide, silicon nitride and silicon oxynitride. The first conductive material (314a, 614a and 616a) may be made of materials, having low electrical resistivity and which give rise to a high Schottky barrier height when the first conductive material (314a, 614a and 616a) is in contact with the contact regions (318, 618 and 620). Such materials may be from any one or more of a group consisting of tantalum nitride, hafnium nitride, tantalum and titanium and the second conductive material (314b, 614b and 616b) may be made of materials, having low electrical resistivity, from any one or more of a group consisting of aluminum, tungsten and copper.

Experimental Results and Discussion

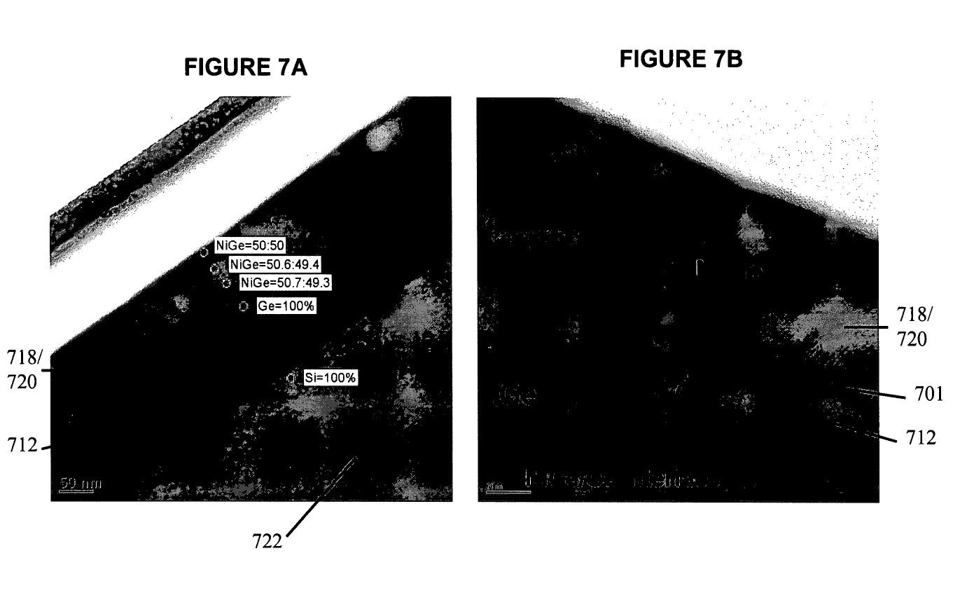

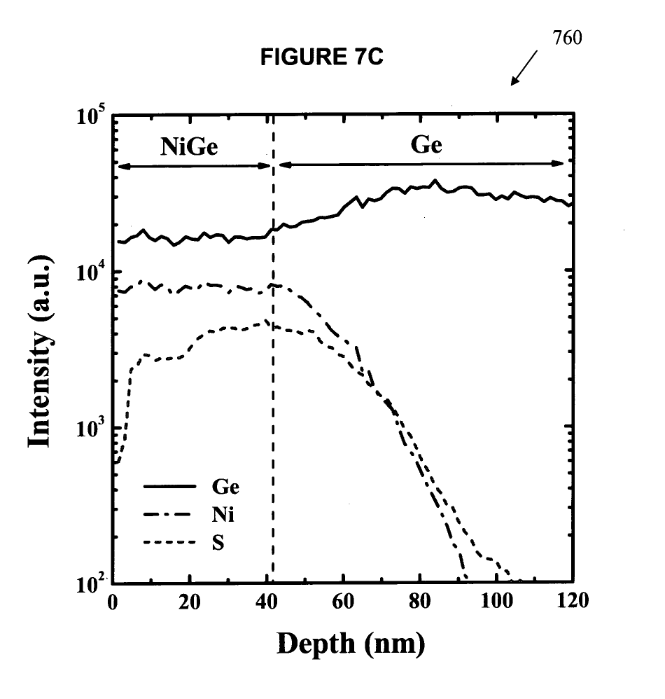

FIGS. 7A and 7B show high resolution transmission electron microscopy (HRTEM) images of a NiGe/Ge junction in a photodetector built in accordance with an embodiment.

FIG. 7A shows a NiGe contact region 718/720 disposed above a Ge detector region 712, where the Ge detector region 712 is disposed above a Si buffer layer 722. From FIG. 7A, it can be seen that the ratio of Ni to Ge varies across the thickness of the NiGe/Ge contact region 718/720.

An excellent interface 701 is formed, with an approximately uniform NiGe thickness of around 70 nm, between the NiGe contact region 718/720 and the Ge detector region 712 to define a NiGe/Ge junction. An X-ray diffraction (XRD) analysis confirmed the formation of a nickel-monogermanide (NiGe) phase after a RTA of 500° C. for 30 seconds.

FIG. 7C shows a secondary-ion-mass spectroscopy (SIMS) depth profile of a sulfur-segregated NiGe Schottky contact of the photodetector of FIGS. 7A and 7B. While germanidation front proceeds, implanted sulfur atoms are observed to segregate at the interface 701 between the NiGe contact region 718/720 and the Ge detector region 712. Due to this segregation, the dangling bonds at the NiGe/Ge interface 701 can be effectively passivated, which concomitantly results in the pinning of germanide Fermi level close to the conduction band edge. An extraction of Schottky barrier height based on a thermionic-emission model at low reverse bias voltage from around 0.05V to around 0.2V reveals the achievement of hole Schottky barrier modulation from around 0.1 eV (for a photodetector without a sulfur-segregation region) to around 0.49 eV as a result of the sulfur-segregation at the NiGe/Ge interface. This leads to the formation of asymmetrical Schottky barriers in MSM photodetectors, where high and low hole barrier height are achieved for contacts with and without sulfur-segregation, respectively.

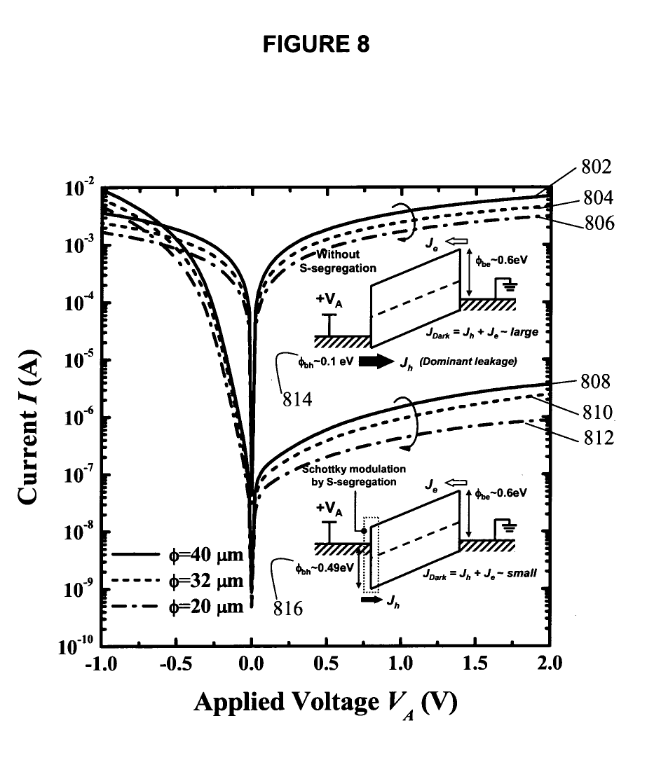

FIG. 8 is a plot of room-temperature current-voltage (I-V) curves to compare the characteristics between a fabricated NiGe Schottky barrier MSM photodetector having sulfur segregation in accordance with an embodiment of the invention, and a photodetector without sulfur segregation. Curves 802, 804 and 806 represent I-V curves for a control photodetector without sulfur segregation and having an effective diameter φ of around 40 μm, 32 μm and 20 μm respectively. Curves 808, 810 and 812 represent I-V curves for a photodetector with sulfur segregation and having an effective diameter φ of around 40 μm, 32 μm and 20 μm respectively.

At an applied bias V_{A} of 1.0 V, high dark current I_{Dark} in the order of around 2.45 mA and around 1.69 mA was observed in the control photodetector without sulfur segregation with a device area of A=804 μm² and A=314 μm² respectively. Such high dark current performance is predominantly attributed to the low hole Schottky barrier height φ_{bh} 814 of around 0.1 eV. However, through the introduction of sulfur segregation at the NiGe/Ge interface (see reference numeral 701 in FIG. 7B), a significant dark current suppression by more than 3 orders of magnitude was achieved as a result of the enhanced hole Schottky barrier φ_{bh} 816 of around 0.49 eV. At V_{A}=1.0 V, the I_{dark} of a sulfur-segregated NiGe Schottky photodetector was measured to be around 0.92 μA and around 0.42 μA for a device area of A=804 μm² and A=314 μm² respectively.

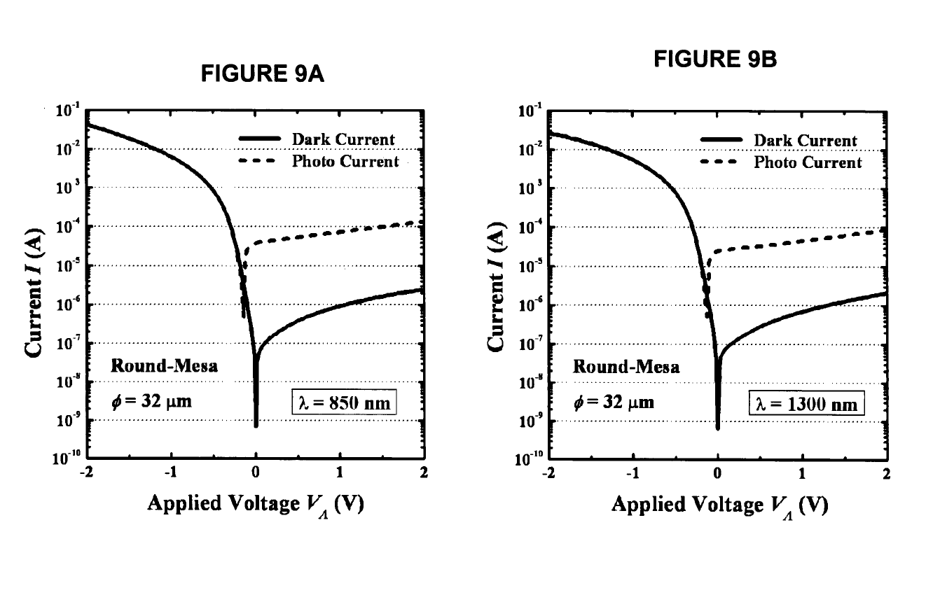

FIGS. 9A and 9B are plots of current versus applied voltage V_{A} for a photodetector built in accordance with an embodiment. The photodetector has an effective diameter φ of around 32 μm. FIGS. 9A and 9B show the photo-response characteristics of a NiGe Schottky photodetector with sulfur-segregation, an embodiment, obtained from optical measurements performed at a photon wavelength of 850 nm and 1300 nm respectively. At V_{A}=1.0 V, good spectra response or a corresponding quantum efficiency of around 0.36 A/W, and around 34% respectively were demonstrated. An appreciable signal-to-noise ratio of around 10² was also observed in these devices.

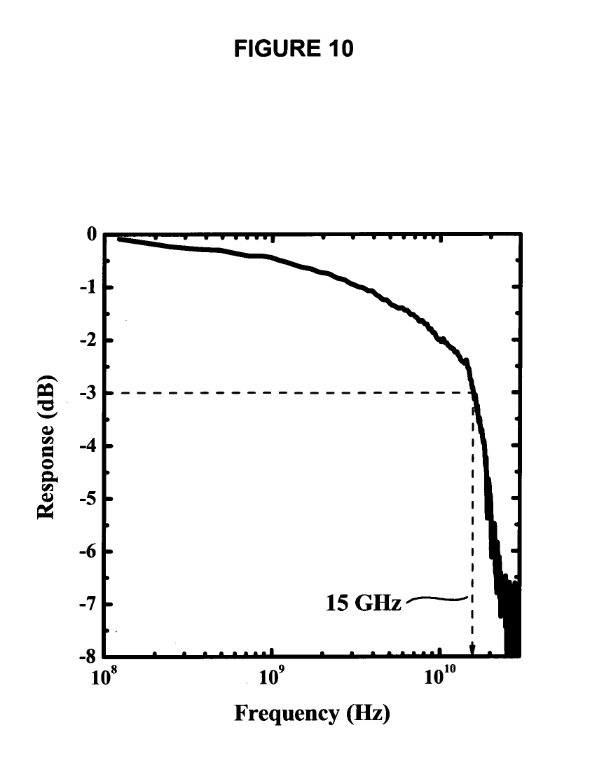

FIG. 10 is a plot of response (dB) versus frequency (Hz) for a photodetector built in accordance with an embodiment. FIG. 9 shows the frequency response of the photodetector measured at an illumination wavelength of 1550 nm, as obtained from the Fourier transform of a pulse response. An around −3 dB bandwidth of around 15 GHz was achieved for an applied bias of 1.0 V, showing comparable speed performance consistent with theoretical modeling results.

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A photodetector comprising:
a detector region;
a first contact region forming an interface with the detector region; and
a first valence mending adsorbate region between the first contact region and the detector region.

2. The photodetector of claim 1 further comprising a second contact region forming an interface with the detector region, wherein the second contact region is electrically isolated from the first contact region.

3. The photodetector of claim 2, further comprising a second valence mending adsorbate region between the second contact region and the detector region.

4. The photodetector of claim 1, wherein the first contact region is disposed above the detector region.

5. The photodetector of claim 1, wherein both the first contact region and the first valence mending adsorbate region are formed within the detector region.

6. The photodetector of claim 1, wherein the first contact region is in contact with the detector region.

7. The photodetector of claim 2, wherein the second contact region is disposed above the detector region.

8. The photodetector of claim 3, wherein both the second contact region and the second valence mending adsorbate region are formed within the detector region.

9. The photodetector of claim 2, wherein the second contact region is in contact with the detector region.

10. The photodetector of claim 1, further comprising:
a passivation layer disposed above the detector region, the passivation layer having a first trench, wherein both the first contact region and the first valence mending adsorbate region are disposed in the first trench.

11. The photodetector of claim 2, further comprising:
a passivation layer disposed above the detector region, the passivation layer having a first trench and a second trench so that the region of the passivation layer between the first trench and the second trench is discontinuous from the remainder of the passivation layer,
wherein both the first contact region and the first valence mending adsorbate region are disposed in the first trench, and wherein the second contact region is disposed in the second trench.

12. The photodetector of claim 3, further comprising:
a passivation layer disposed above the detector region, the passivation layer having a first trench and a second trench so that the region of the passivation layer between the first trench and the second trench is discontinuous from the remainder of the passivation layer,
wherein both the first contact region and the first valence mending adsorbate region are disposed in the first trench, and wherein both the second contact region and the second valence mending adsorbate region are disposed in the second trench.

13. The photodetector of claim 1, further comprising:
a waveguide layer, wherein the detector region is disposed above the waveguide layer.

14. The photodetector of claim 13, further comprising:
a buffer layer disposed between the detector region and the waveguide layer.

15. The photodetector of claim 14, further comprising:
a compliant layer disposed between the buffer layer and the waveguide layer.

16. The photodetector of claim 13, further comprising:
an isolation region disposed above the waveguide layer and adjacent to opposing edges of the detector region.

17. The photodetector of claim 13, further comprising:
an isolation layer, wherein the waveguide layer is disposed above the isolation layer.

18. The photodetector of claim 10, further comprising:
a first electrode disposed above the first contact region and in contact with the first trench.

19. The photodetector of claim 11, further comprising:
a first electrode disposed above the first contact region and in contact with the first trench, and a second electrode disposed above the second contact region and in contact with the second trench.

20. The photodetector of claim 18, wherein the first electrode comprises at least a first conductive material and a second conductive material, wherein the first conductive material is in contact with the first contact region and the first trench.

21. The photodetector of claim 19, wherein the second electrode comprises at least a first conductive material and a second conductive material, wherein the first conductive material is in contact with the second contact region and the second trench.

22.-32. (canceled)

33. A method of forming a photodetector, the method comprising:
forming a detector region;
forming a first contact region as an interface with the detector region; and
forming a first valence mending adsorbate region between the first contact region and the detector region.

34.-65. (canceled)

66. A photodetector comprising:
a detector region;
a first contact region; and
a first valence mending adsorbate region forming an interface between the detector region and the first contact region, wherein the first valence mending adsorbate region passivates dangling bonds between the first contact region and the detector region.
